(19) United States
(12) Patent Application Publication
(10) Pub. No.: US 2025/0326631 A1
(43) Pub. Date: Oct. 23, 2025

(54) INTEGRATED MEMS MICROPHONE PERFORMANCE ENHANCEMENT WITH A MEMBRANE

(71) Applicant: Meta Platforms Technologies, LLC, Menlo Park, CA (US)

(72) Inventors: Limin Zhou, Redmond, WA (US); Yu-Chun Hsu, San Jose, CA (US)

(21) Appl. No.: 19/173,700

(22) Filed: Apr. 8, 2025

Related U.S. Application Data
(60) Provisional application No. 63/637,110, filed on Apr. 22, 2024.

(51) Int. Cl. B81B 7/00; B81C 1/00

(52) U.S. Cl. CPC B81B 7/0061; B81C 1/00309; B81B 2201/0257; B81B 2203/0127; B81B 2207/015; B81B 2207/11; B81C 2203/0109

(57) ABSTRACT

Systems and methods for a MEMS microphone package are disclosed. The MEMS microphone package may include a first port to direct sound to a MEMS system, including a die substrate, an acoustic membrane, and one or more plates. The MEMS microphone package may include an ASIC to produce microphone output based on an electrical signal, a PCB, a lid, and a second port. The first port and the second port may define a front volume and a back volume respectively. The second port may increase the back volume to improve sensitivity and reduce the acoustic sensor's noise floor to improve signal-to-noise ratio.

### CROSS-REFERENCE TO RELATED APPLICATIONS

This application claims priority to U.S. Provisional Application No. 63/637,110, filed Apr. 22, 2024, entitled “Integrated MEMS Microphone Performance Enhancement With A Membrane,” which is incorporated by reference herein in its entirety.

### TECHNOLOGICAL FIELD

Exemplary embodiments of this disclosure relate generally to a method for improving acoustic performance of electronic devices.

### BACKGROUND

Electronic devices may comprise a micro-electromechanical systems (MEMS) capacitive microphone. A MEMS diaphragm forms a capacitor and sound pressure waves cause movement of the diaphragm. MEMS microphones may include a second semiconductor die which functions as an audio preamplifier, converting the changing capacitance of the MEMS to an electrical signal.

### BRIEF SUMMARY

According to an aspect of the application methods and systems for improving acoustic performance associated with a micro-electromechanical systems (MEMS) microphone package are described. The methods and systems may increase the air volume associated with a MEMS microphone package to improve acoustic performance of a device, wherein a membrane may be added to the system to block obstructions from the MEMS membrane.

In an example, a MEMS microphone package may include a lid to protect inner components of the MEMS package; an application-specific integrated circuit (ASIC) configured to produce the microphone output based on an electrical signal; a printed circuit board (PCB), wherein the ASIC may be attached; a MEMS system attached to the PCB comprising a MEMS chip, an acoustic sensor, wherein the acoustic sensor may comprise an acoustic membrane and one or more plates; a first port configured to direct sound waves to the acoustic sensor, wherein the positions of the first port defines a front volume; and a second port configured to increase a back volume associated with the MEMS package. A membrane, associated with the second port, configured to block an obstruction from entering the MEMS package while allowing air to flow through the membrane.

In some examples, a microphone system is provided. The microphone system may include a printed circuit board, and an application-specific integrated circuit attached to the printed circuit board. The application-specific integrated circuit may produce a microphone output from an electrical signal. The microphone system may also include a MEMS component attached to the printed circuit board. The MEMS component may include a plate, an acoustic sensor, and a MEMS die substrate. A front volume of air may be formed between the printed circuit board and the acoustic sensor. The microphone system may also include a lid secured to the printed circuit board. The lid may form a back volume of air around the application-specific integrated circuit and the MEMS component. The microphone system may also include a first port formed in the printed circuit board. The first port may be positioned to direct sound waves, through the front volume, toward the acoustic sensor. The microphone system may also include a second port formed in the lid to increase air volume into the back volume.

In some other examples, a method may be provided. The method may include attaching an application-specific integrated circuit to a printed circuit board. The method may further include attaching a MEMS component to the printed circuit board. The MEMS component may include a plate, an acoustic sensor, and a MEMS die substrate. A front volume of air may be formed between the printed circuit board and the acoustic sensor. The method may further include securing a lid to the printed circuit board to form a back volume of air around the application-specific integrated circuit and the MEMS component. The method may further include directing sound waves, through the front volume, toward the acoustic sensor. The sound waves may be directed via a first port in the printed circuit board. The method may further include increasing air volume into the back volume via a second port formed in the lid. The method may further include producing, via the application-specific integrated circuit, a microphone output via an electric signal.

In yet some other examples, another microphone system may be provided. The microphone system may include a printed circuit board, and an application-specific integrated circuit attached to the printed circuit board. The application-specific integrated circuit may produce a microphone output from an electrical signal. The microphone system may further include a MEMS component attached to the printed circuit board. The MEMS component may include a plate, an acoustic sensor, and a MEMS die substrate. A front volume of air may be formed between the printed circuit board and the acoustic sensor. The microphone system may further include a lid secured to the printed circuit board. The lid may form a back volume of air around the application-specific integrated circuit and the MEMS component. The microphone system may further include a first port formed in the printed circuit board. The first port may be positioned to direct sound waves, through the front volume, toward the acoustic sensor. The microphone system may further include a second port formed in the lid to increase air volume into the back volume. The microphone system may further include an enclosure surrounding the lid and the printed circuit board. The enclosure may include an opening to direct the sound waves to the first port. The microphone system may further include a flex securing the enclosure to the printed circuit board.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

The summary, as well as the following detailed description, is further understood when read in conjunction with the appended drawings. For the purpose of illustrating the disclosed subject matter, there are shown in the drawings exemplary embodiments of the disclosed subject matter; however, the disclosed subject matter is not limited to the specific methods, and devices disclosed. In addition, the drawings are not necessarily drawn to scale. In the drawings:

FIG. 1A illustrates an example bottom port MEMS microphone package.

FIG. 1B illustrates an example top port MEMS microphone package.

FIG. 2A illustrates a bottom port MEMS microphone package, in accordance with an example of the present disclosure.

FIG. 2B illustrates a bottom port MEMS microphone package integrated in a product, in accordance with an example of the present disclosure.

FIG. 3A illustrates a top port MEMS microphone package, in accordance with an example of the present disclosure.

FIG. 3B illustrates a top port MEMS microphone package integrated in a product, in accordance with an example of the present disclosure.

FIG. 4 illustrates a graph of frequency response of a membrane, in accordance with an example of the present disclosure.

FIG. 5 illustrates an example head mounted display (HMD) in accordance with an embodiment.

FIG. 6 is a diagram of an exemplary network environment in accordance with an embodiment.

FIG. 7 is a diagram of an exemplary audio device in accordance with an embodiment.

FIG. 8 illustrates an example operational flow in accordance with various aspects of the present disclosure.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

The present disclosure may be understood more readily by reference to the following detailed description taken in connection with the accompanying figures and examples, which form a part of this disclosure. It is to be understood that this disclosure is not limited to the specific devices, methods, applications, conditions or parameters described and/or shown herein, and that the terminology used herein is for the purpose of describing particular embodiments by way of example only and is not intended to be limiting of the claimed subject matter.

Some embodiments of the present invention will now be described more fully

hereinafter with reference to the accompanying drawings, in which some, but not all embodiments of the invention are shown. Indeed, various embodiments of the invention may be embodied in many different forms and should not be construed as limited to the embodiments set forth herein. Like reference numerals refer to like elements throughout. As used herein, the terms “data,” “content,” “information” and similar terms may be used interchangeably to refer to data capable of being transmitted, received, and/or stored in accordance with embodiments of the invention. Moreover, the term “exemplary,” as used herein, is not provided to convey any qualitative assessment, but instead merely to convey an illustration of an example. Thus, use of any such terms should not be taken to limit the spirit and scope of embodiments of the invention.

As defined herein a “computer-readable storage medium,” which refers to a non-transitory, physical, or tangible storage medium (e.g., volatile, or non-volatile memory device), may be differentiated from a “computer-readable transmission medium,” which refers to an electromagnetic signal.

It is to be understood that the methods and systems described herein are not limited to specific methods, specific components, or to particular implementations. It is also to be understood that the terminology used herein is for the purpose of describing particular embodiments only and is not intended to be limiting.

References in this description to “an example”, “one example”, or the like, may mean that the particular feature, function, or characteristic being described is included in at least one example of the present invention. Occurrences of such phrases in this specification do not necessarily all refer to the same example, nor are they necessarily mutually exclusive.

Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable. It is to be understood that the terminology used herein is for the purpose of describing particular aspects only and is not intended to be limiting.

It is to be appreciated that certain features of the disclosed subject matter which are, for clarity, described herein in the context of separate embodiments, may also be provided in combination in a single embodiment. Conversely, various features of the disclosed subject matter that are, for brevity, described in the context of a single embodiment, may also be provided separately or in any sub-combination. Further, any reference to values stated in ranges includes each and every value within that range. Any documents cited herein are incorporated herein by reference in their entireties for any and all purposes.

Many electronic devices may include methods and systems to capture audio. In such audio capturing systems associated with electronic devices a high performance may be desired to achieve high fidelity sound recordings. A high performance may be defined by a wide bandwidth, higher sensitivity, or a high signal-to-noise ratio (SNR). Due to size constraints of many electronic devices, many electronic devices may comprise a micro-electromechanical systems (MEMS) capacitive microphone. The size constraints associated with electronic devices may affect the target acoustic performance of the electronic device. Due to the properties of MEMS microphones, the acoustic performance may be limited by the air volume available to the audio system (e.g., MEMS microphone package). An improved MEMS microphone package may enhance acoustic performance of an electronic device.

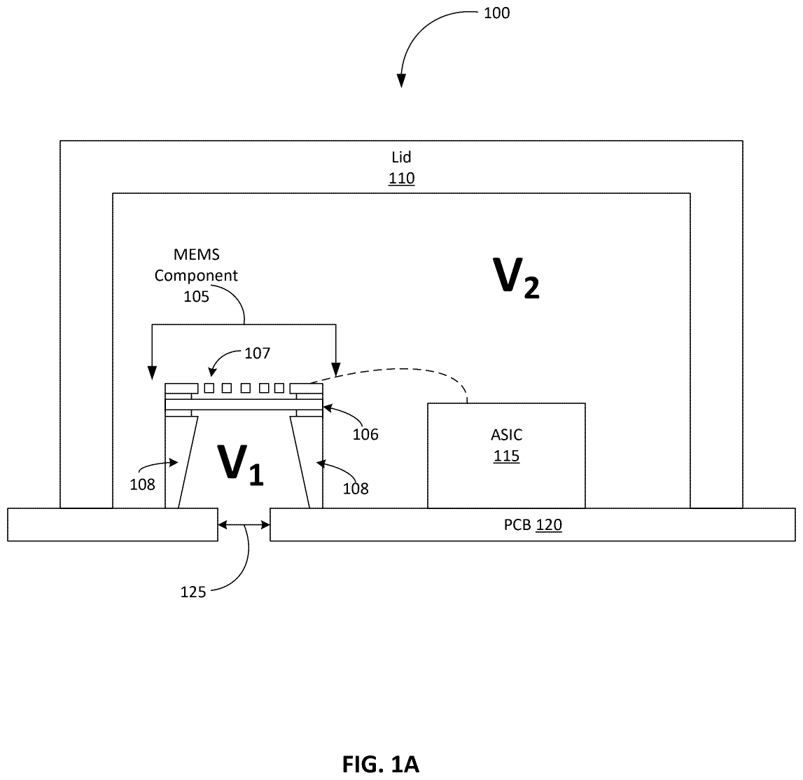

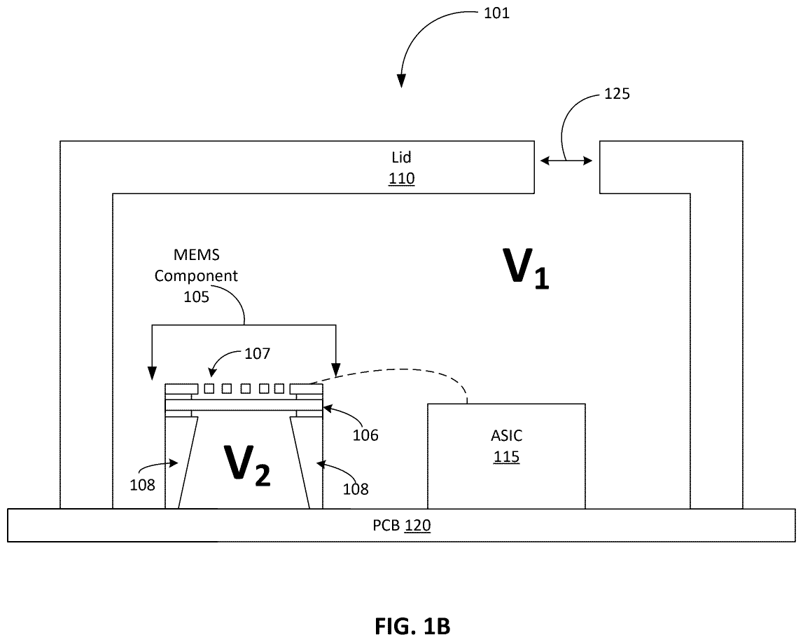

FIG. 1A illustrates an example micro-electromechanical systems (MEMS) microphone package 100. In some examples, the digital microphones may utilize pulse density modulation (PDM), which produces a highly oversampled single-bit data-stream. The density of the pulses on the output of a microphone using pulse density modulation is similar to the pulse width modulation (PWM) used in class D amplifiers. The difference is that pulse width modulation uses a constant time between pulses and encode the signal in the pulse width, while pulse density modulation uses a constant pulse width and encodes the signal in the time between pulses.

In many examples, the MEMS package 100 may need to have a port 125 to allow sound to reach the acoustic sensor (e.g., MEMS sensor). The port 125 may be located either in the lid 110, the orientation of the port 125 in FIG. 1A may be commonly referred to as a bottom port MEMS microphone package, wherein the port 125 is an opening in PCB 120 positioned under the MEMS component 105. Bottom port microphones (e.g., as illustrated in FIG. 1A) may require a hole in the circuit board (e.g., PCB 120) they are mounted on to allow sound to enter the MEMS package 100 via port 125. The positioning of the components of the MEMS package 100 may create air volumes (e.g., a front volume (V₁) and a back volume (V₂)) that may affect the quality of the sound captured via MEMS component 105. In the example of FIG. 1A, the port 125 may define where the front volume (V₁) is located, where the front volume (V₁) may be made up of the air captured in the area between the port 125 and the acoustic membrane 106 of the MEMS component 105. Conversely the air volume captured in the area between the lid 110 and MEMS component 105 may be referred to as a back volume (V₂). The back volume (V₂) may not have direct access to the port 125 like the front volume (V₁). Many of the attributes of the MEMS package 100 may be dependent on the air volumes (e.g., front volume (V₁) and back volume (V₂)) captured in the package 100. For example, the sensitivity of MEMS package 100 may be dependent on the back volume (V₂), as the back volume may aid in defining a stiffness of the MEMS component (e.g., MEMS component 105). In many bottom port MEMS microphone systems, the acoustic sensor may be mounted directly over the port 125 resulting in a relatively small front volume (V₁) and a relatively large back volume (V₂) which may represent a relatively high sensitivity of the MEMS system. The larger back volume (V₂) may make it easier for the acoustic membrane 106 (e.g., acoustic sensor 106) to move in response to sound waves, introduced to the MEMS package 100 via port 125, which may improve the sensitivity of the microphone and lead to higher signal-to-noise ratios (SNR). A large back volume (V₂) may also improve the MEMS microphone's low frequency response. The sensitivity of MEMS microphones may be inversely proportional to the stiffness associated with the MEMS component (e.g., MEMS component 105). For example, in MEMS packages (e.g., MEMS package 100) where the back volume is large the stiffness of the MEMS component (e.g., MEMS component 105) may be low thus the MEMS microphone may have higher sensitivity. Conversely, in some systems a top port may be used. The components of top port microphones have traditionally been similar to bottom port microphones. A difference between top port and bottom port microphones is that the port 125 is located in the lid 110 instead of in the PCB 120. For such examples (e.g., FIG. 1B), moving port 125 to the lid 110 turns what was previously the front volume (V₁) into the back volume (V₂) and the back volume (V₂) to the front volume (V₁). Thus, in top port systems the front volume (V₁) may be large, and the back volume (V₂) may be small. As such top port microphones may be discussed in more detail in the following paragraphs.

FIG. 1B illustrates a top port MEMS microphone package 101. The MEMS microphone package 101 may comprise an of the devices and/or features of FIG. 1A, such as a MEMS component 105 an acoustic sensor 106 (also herein referred to as an acoustic membrane 106), a plate 107, MEMS die substrate 108, a lid 110, an ASIC 115, a PCB 120, and a port 125. As illustrated in FIG. 1B, the port 125 may be positioned on the lid 110, wherein the positioning of the port 125 may be refer to a top port MEMS package. Top port microphones may require a hole in the lid (e.g., lid 110) to allow sound (e.g., sound waves) to enter the MEMS package 101 via port 125. It is contemplated that the port 125 may be located at any position along the length of lid 110. The acoustic membrane 106 may divide the interior of the MEMS package 101 into two sections, wherein the area between the port 125 (located on lid 110) and the acoustic membrane 106 may be referred to as a front volume (V₁) and the section on the other side of the acoustic membrane 106 may be refer to a back volume (V₂), wherein the back volume (V₂) maybe defined as the area between the MEMS component 105 and PCB 120. Many of the attributes of the MEMS package 101 may be dependent on the air volumes (e.g., front volume (V₁) and back volume (V₂)) captured in the package 101. For example, the sensitivity of MEMS package 101 may be dependent on the back volume (V₂), as the back volume may aid in defining a stiffness of the MEMS component (e.g., MEMS component 105). In examples, the smaller back volume (V₂) top port MEMS microphones may make it more difficult for the acoustic membrane 106 to move, which may decrease the sensitivity of the acoustic sensor 106 and lead to a lower SNR. The sensitivity of MEMS microphones may be inversely proportional to the stiffness associated with the MEMS component. For example, in MEMS packages (e.g., MEMS package 101) where the back volume is small the stiffness of the MEMS component (e.g., MEMS component 105) may be high thus the MEMS microphone may have low sensitivity. The smaller back volume (V₂) may also increase a thermoviscous noise associated with the MEMS microphone package 101, thus adding to a lower SNR. The larger front volume (V₁) between the port and the acoustic membrane 106 may lower the resonant frequency, hurting the microphone's high frequency response. In top port MEMS microphone package 101, the lower SNR may indicate a microphone with a poor performance in comparison to a bottom port microphone that may be similar to what is shown in FIG. 1A. In some examples, the low SNR ratio may be combined with an increased low frequency roll-off (LFRO).

It is contemplated that it may be a manufacturers choice to use a top port or bottom port orientation of a MEMS microphone package based on factors such as but not limited to, a location of the microphone in the product and manufacturing considerations. Further manufacturers may determine the MEMS package configuration based on performance of the MEMS microphone package.

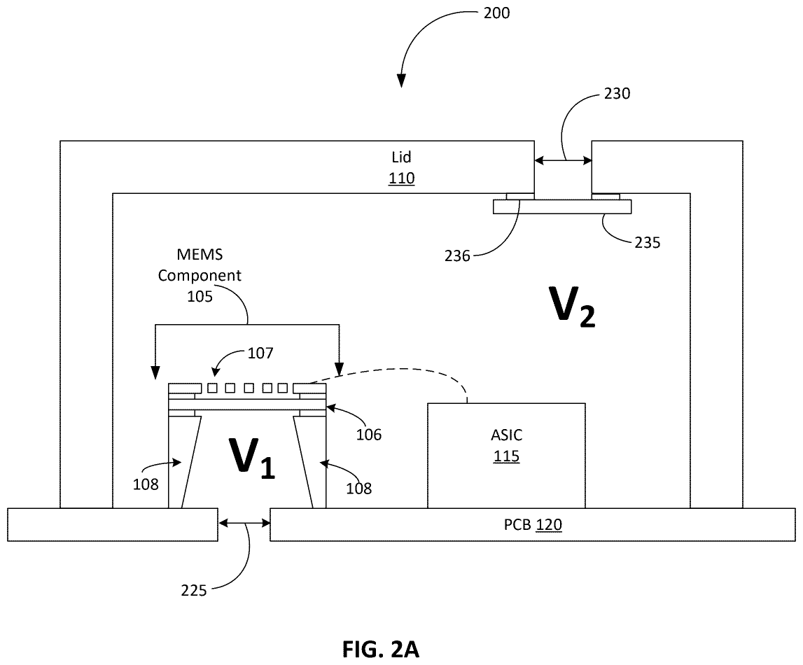

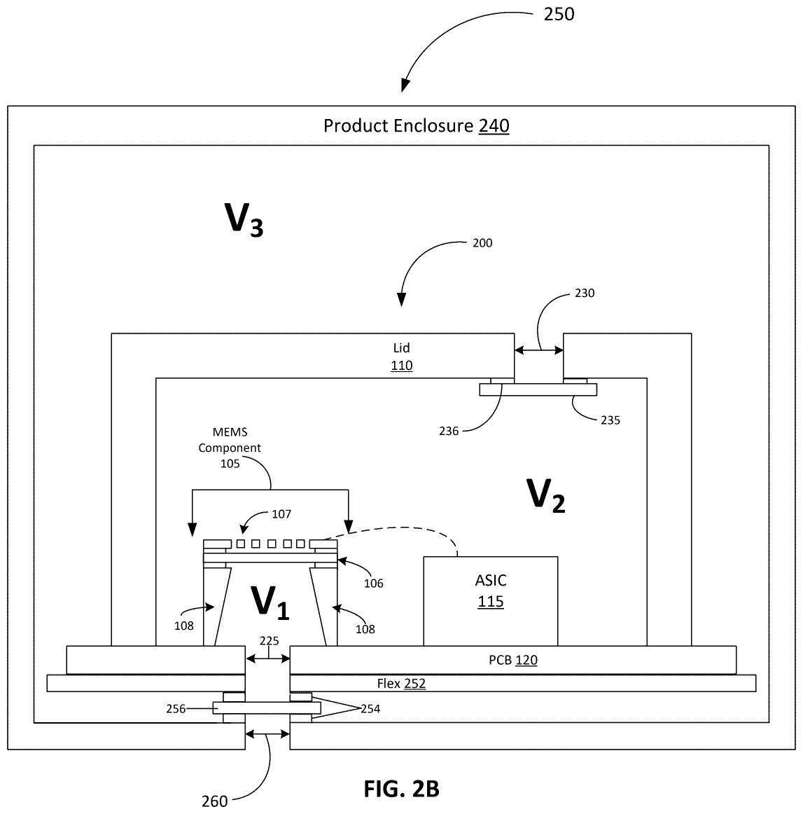

FIG. 2A illustrates a bottom port MEMS microphone package 200, in accordance with an example of the present disclosure. The MEMS microphone package 200 may comprise any of the devices and/or features of FIG. 1A, such as a MEMS component 105, an acoustic sensor 106 (also herein referred to as an acoustic membrane 106), a plate 107, MEMS substrate die 108, a lid 110, an ASIC 115, and a PCB 120. The MEMS microphone package 200 may comprise one or more ports, wherein a first port 225 may be defined similar to port 125 of FIG. 1A and a second 230 port positioned on lid 110. The second port may be configured to increase the back volume (V₂) associated with the MEMS microphone package 200, wherein the back volume (V₂) may be defined by the volume of air between the MEMS component 105 and the lid 110. The second port 230 may be associated with a membrane 235, wherein the membrane may be configured to block debris or any unwanted particle from MEMS microphone package 200 and allow air to pass through to MEMS microphone package 200. The membrane 235 may be any suitable membrane that may allow air to pass through to MEMS microphone package 200, such as but not limited to, an expanded polytetrafluoroethylene (ePTFE) membrane. It is contemplated that the membrane may be comprised of any material for different purposes, such as but not limited to, tape, mesh, etc. The membrane may be attached to the lid 110 by any suitable means, such as but not limited to, a pressure sealed adhesive (PSA) 236. The positioning of the components of the MEMS package 200 may create air volumes (e.g., a front volume (V₁) and a back volume (V₂)) that may affect the quality of the sound captured via MEMS component 105. In the example of FIG. 2A, the first port 225 may define where the front volume (V₁) is located, where the front volume (V₁) may be made up of the air captured in the area between the first port 225 and the acoustic membrane 106 of the MEMS component 105. Conversely, the air volume captured in the area between the lid 110 and MEMS component 105 may be referred to as a back volume (V₂). The back volume (V₂) may have direct access to the second port 230. Many of the attributes of the MEMS package 200 may be dependent on the air volumes (e.g., front volume (V₁) and back volume (V₂)) captured in the package 200. For example, the sensitivity of MEMS package 200 may be dependent on the back volume (V₂), as the back volume may aid in defining a stiffness associated with the MEMS component 105. The sensitivity of MEMS microphones may increase at higher frequencies of sound. This increase in sensitivity may be caused by the interaction between the air in the first port 225 and the air in the back volume (V₂). In MEMS packages that use bottom ports, the acoustic sensor 106 may be mounted directly over the first port 225, which may result in a relatively small front volume (V₁) and a relatively large back volume (V₂).

FIG. 2B may illustrate a bottom port MEMS microphone package 200 in a product 250. FIG. 2B may depict an example of how the back volume may be increased in comparison to bottom port MEMS microphone packages. The product 250 may be any suitable electronic device such as a desktop computer, notebook or laptop computer, netbook, a tablet computer (e.g., a smart tablet), e-book reader, Global Positioning System (GPS) device, camera, personal digital assistant (PDA), handheld electronic device, cellular telephone, smartphone, smart glasses, augmented/virtual reality device, smart watches, charging case, or any other suitable electronic device, or any suitable combination thereof. The product 250 may comprise a MEMS microphone package 200 that may be housed in a product enclosure 240, where the MEMS microphone package 200 may be attached to a flex 252 that may attach the MEMS microphone package 200 to the product enclosure 240 via an adhesive 254 and mesh 256. The combination of the adhesive 254 and mesh 256 may be configured to protect the MEMS package 200 from an outside environment, via an opening 260 in the product enclosure 240. The product 250 may receive sound waves via the opening 260, which may direct the sound waves (e.g., sound) to the MEMS microphone package 200. The sound may then pass through to the first port 225 and interact with components of MEMS microphone package 200 that may comprise the front volume (e.g., area between MEMS component 105 and PCB 120). Conversely the air volume captured in the area between the lid 110 and MEMS component 105, also referred to as V₂, and the area between the MEMS package 200 and the product enclosure 240, also referred to as V₃, may comprise the back volume. Due to membrane 235, the MEMS microphone package 200 may have access to the air volume associated with the product enclosure 240 thus greatly increasing the back volume associated with the MEM microphone package 200 (e.g., V₂+V₃). The large back volume (V₂+V₃) may increase the sensitivity of MEMS microphones may allow for easier and greater movement of the acoustic membrane 106 (e.g., acoustic sensor 106) in response to sound waves as the back volume (V₂+V₃) may be increased via the second port 230 and product enclosure 240 arrangement thus, increasing the sensitivity of the MEMS component 105. The increased back volume (V₂+V₃) may improve the sensitivity of the MEMS microphone and lower noise floor compared to the conventional bottom port MEMS systems (e.g., FIG. 1A). As such, the lower noise floor and improved sensitivity associated with the MEMS package 200 may lead to a higher SNR, which may span a frequency range of relative to human hearing capabilities.

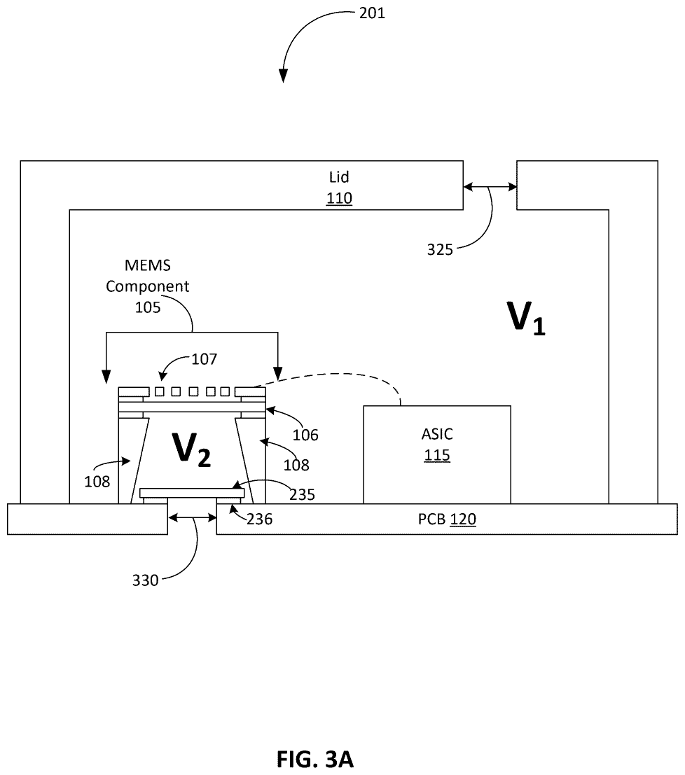

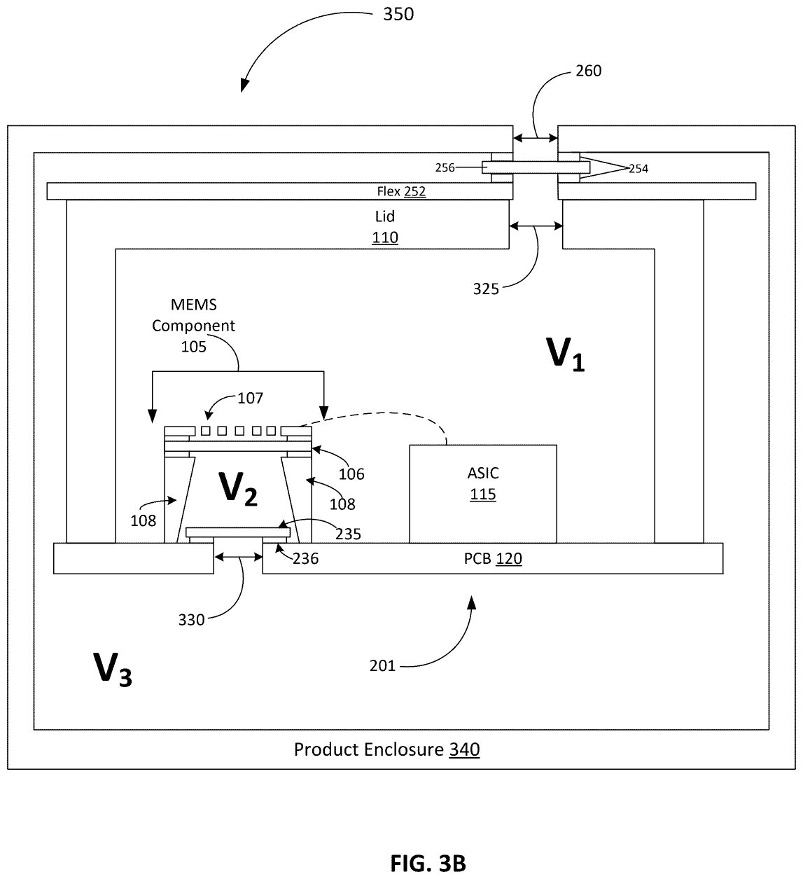

FIG. 3A illustrates a top port MEMS microphone package 201, in accordance with an example of the present disclosure. The MEMS microphone package 201 may comprise any of the devices and/or features of FIG. 1A, such as a MEMS component 105, an acoustic sensor 106 (also herein referred to as an acoustic membrane 106), a plate 107, MEMS die substrate 108, a lid 110, an ASIC 115, and a PCB 120. The MEMS microphone package 201 may comprise one or more ports, wherein a first port 325 may be defined similar to port 125 of FIG. 1B and a second port 330 positioned on PCB 120. The second port 330 may be configured to increase the back volume (V₂) associated with the MEMS microphone package 201, wherein the back volume (V₂) may be defined by the volume of air between the MEMS component 105 and the second port 330. The second port 330 may be associated with a membrane 235, wherein the membrane may be configured to block debris or any unwanted particle from MEMS microphone package 201 and allow air to pass through to MEMS microphone package 201. The membrane 235 may be any suitable membrane that may allow air to pass through to MEMS microphone package 201, such as but not limited to, an expanded polytetrafluoroethylene (ePTFE) membrane. It is contemplated that the membrane may be comprised of any material for different purposes, such as but not limited to, tape, mesh, etc. The membrane may be attached to the PCB 120 by any suitable means, such as but not limited to, a pressure sealed adhesive (PSA) 236. The positioning of the components of the MEMS package 201 may divide air volumes (e.g., a front volume (V₁) and a back volume (V₂)) that may affect the quality of the sound captured via MEMS component 105.

In the example of FIG. 3A, the first port 325 may define where the front volume (V₁) is located, where the front volume (Vi) may be made up of the air captured in the area between the first port 325 and the acoustic membrane 106 of the MEMS component 105. Conversely, the air volume captured in the area between the MEMS component 105 and the second port 330 may be referred to as a back volume (V₂), wherein the back volume (V₂) may be larger than a conventional top port MEMS microphone package (e.g., MEMS microphone package 101 of FIG. 1B) due to the second port 330. The back volume (V₂) may have direct access to the second port 330. Many attributes of the MEMS package 201 may be dependent on the air volumes (e.g., front volume (V₁) and back volume (V₂)) captured in the MEMS microphone package 201. For example, the sensitivity of MEMS package 201 may be dependent on the back volume (V₂), as the back volume may aid in defining a stiffness associated with the MEMS component (e.g., MEMS component 105). The sensitivity of MEMS microphones may increase at higher frequencies of sound. This increase in sensitivity may be caused by the interaction between the air in the first port 325 and the air in the back volume (V₂). In MEMS packages that may use a top port, the acoustic sensor 106 may be mounted directly over the second port 330, which may result in a relatively small back volume (V₂) and a relatively large front volume (V₁). The orientation of the second port 330 with the acoustic sensor 106 positioned directly over the second port 330 may create a small back volume (V₂). Conversely, the orientation of the first port 325 in relation to the MEMS component 105 may constitute a large front volume (V₁). Sound waves may be introduced to the MEMS microphone package 201 via the first port 325 and air may be able to pass through the package 201 via second port 330.

FIG. 3B may illustrate a top port MEMS microphone package 201 in a product 350. FIG. 3B may depict an example of how the back volume may be increased in comparison to conventional top port MEMS microphone packages. The product 350 may comprise any of the devices and/or features of FIG. 2B and FIG. 3A, such as but not limited to, a MEMS microphone package 201, a product enclosure 340, a flex 252, an adhesive 254, mesh 256, and an opening 260. The combination of the adhesive 254 and mesh 256 may be configured to protect the MEMS package 201 from an outside environment, via an opening 260 in the product enclosure 340. The product 350 may receive sound waves via the opening 260, which may direct the sound waves (e.g., sound) to the MEMS microphone package 201. The sound may then pass through to the first port 325 and interact with components of MEMS microphone package 201 that may comprise the front volume (e.g., area between MEMS component 105 and lid 110). Conversely the air volume captured in the area between the PCB 120 and MEMS component 105, also referred to as V₂ and the area between the MEMS package 201 and the product enclosure 340, also referred to as V₃, may comprise the back volume (V₂+V₃). Due to membrane 235, the MEMS microphone package 201 may have access to the air volume associated with the product enclosure 340 thus greatly increasing the back volume associated with the MEM microphone package 201 (e.g., V₂+V₃). The larger back volume, in comparison to a conventional top port MEMS microphone package (e.g., MEMS microphone package 101 of FIG. 1B) may increase the sensitivity of MEMS microphone and may allow for easier and greater movement of the acoustic membrane 106 (e.g., acoustic sensor 106) in response to sound waves as the back volume (V₂+V₃) may be increased via the second port 330 and product enclosure 340 arrangement. The increased back volume (V₂+V₃) may improve the sensitivity of the MEMS microphone and lower noise floor, compared to the conventional top port MEMS package 101 as illustrated in FIG. 1B. As such, the lower noise floor and improved sensitivity associated with the MEMS package 201 may lead to a higher SNR, which may span a frequency range relative to human hearing capabilities.

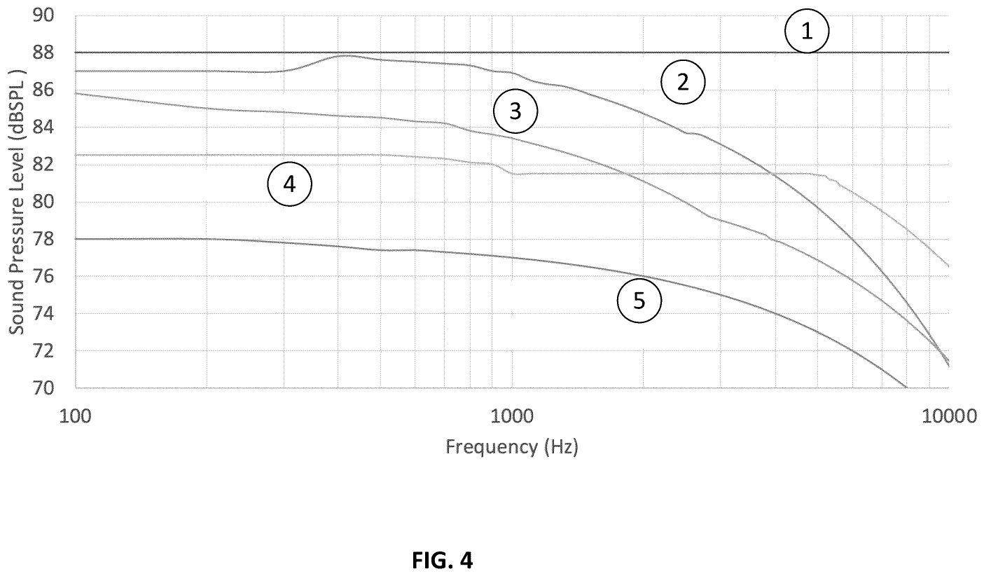

FIG. 4 illustrates a graph of frequency response of a membrane (e.g., membrane 235), in accordance with an example of the present disclosure. Each of the lines 1, 2, 3, 4, 5 may illustrate the frequency response of the membrane with varying thicknesses. It is contemplated that the membrane 235 may be of any suitable thickness necessary for the device. Line 1 may illustrate the frequency response of a MEMS package where there is no membrane 235 associated with the second port (e.g., second port 230, 330). Looking at line 2, line 3, line 4, and line 5 the thickness of the membrane 235 may be increased, respectively, where line 5 may illustrate the largest thickness of membrane 235 and line 2 may illustrate the thinnest thickness of membrane 235. In some examples, the thickness of membrane 235 may directly correspond to membrane impedance thus the acoustic membrane 106 sensitivity may be affected in relation to the thickness of membrane 235. For example, a thick membrane 235 may block more particles from the MEMS microphone package and allow for deep dives into water, but due to the thickness of the membrane 235 the air volume may be affected, decreasing the back volume (V2+V3), specifically decreasing V3, resulting in a less sensitive acoustic membrane 106 and a higher SNR. Alternatively, for example, a thin membrane 235 may allow more particles through to the MEMS package, thus resulting in an increased back volume (V2+V3) compared to a thicker membrane 235 and increased sensitivity of acoustic membrane 106. Although a thin membrane 235 may increase sensitivity of the acoustic membrane 106, the thin membrane may be more susceptible to particles damaging the MEMS package, for example, some very thin membranes 235 may allow water or debris to pass through to the MEMS package thus damaging or reducing the function of the MEMS package, potentially decreasing sensitivity of acoustic membrane 106, and decreasing SNR. As illustrated, while membrane 235 thickness is increased microphone performance may degrade. For example, a device may be configured to be used underwater at a particular depth, as such the device may utilize a thicker membrane 235 that may allow for some air particles to pass through the membrane and block water particles. In such an example, water may be blocked from the components of the MEMS package via membrane 235 and that membrane 235 may be able to withstand the water pressure associated with the depth of a body of water, but with less air particles (e.g., back volume) available to the MEMS package the sensitivity and SNR of the MEMS microphone may be decreased.

In FIG. 2B and FIG. 3B the back volume is illustrated and defined as V₂+V₃ where the V₃ may be defined by the space between a MEMS package and a product enclosure. It is contemplated that V₃ may be any volume or space relative to the MEMS package, wherein the second port (e.g., second port 230, second port 330) may allow for the transfer of air particles between the MEMS package and the environment surrounding the MEMS package. For example, a MEMS package (e.g., MEMS package 100) may be placed in a closed room, in such an example the space between the MEMS package and the walls associated with the closed room may define V₃.

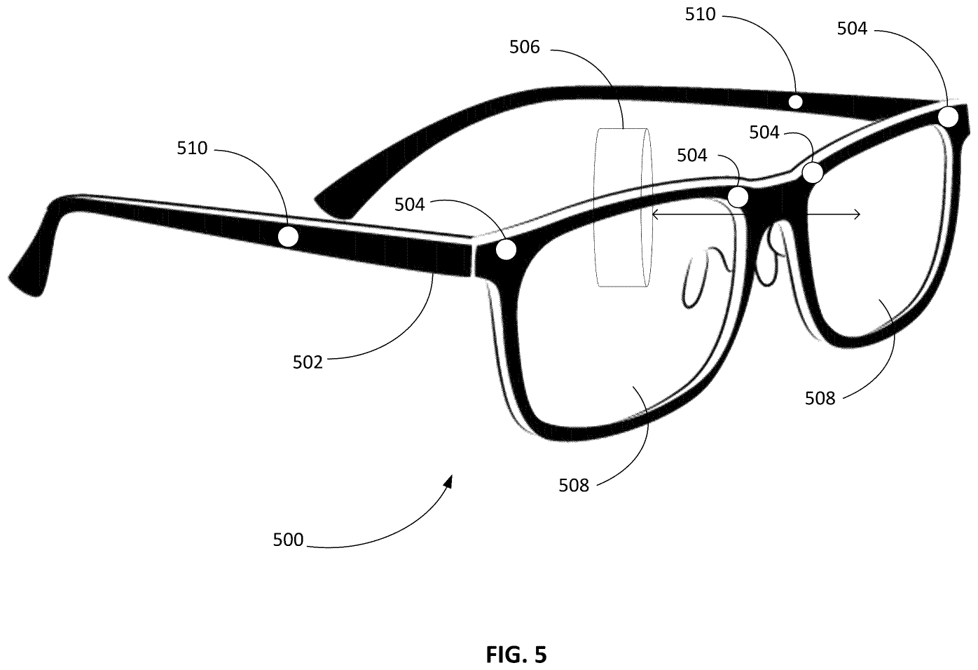

FIG. 5 illustrates an example HMD 500 associated with artificial reality content. HMD 500 may include frame 502 (e.g., an eyeglasses frame), a camera 504, a display 508, and an audio device 510 (e.g., speakers/microphone). Display 508 may be configured to direct images to a surface 506 (e.g., a user's eye or another structure). In some examples, HMD 500 may be implemented in the form of augmented-reality glasses. Accordingly, display 508 may be at least partially transparent to visible light to allow the user to view a real-world environment through the display 508. The audio device 510 (e.g., speakers/microphones) that may provide audio associated with augmented-reality content to users and capture audio signals.

Tracking of surface 506 may be beneficial for graphics rendering or user peripheral input. In many systems, HMD 500 design may include one or more cameras 504 (e.g., a front facing camera(s) away from a user or a rear facing camera(s) towards a user. Camera 504 may track movement (e.g., gaze) of eye or line of sight associated with the user. HMD 500 may include an eye tracking system to track the vergence movement of a user. Camera 504 may capture images or videos of an area, or capture video or images associated with surface 506 depending on the directionality and view of camera 504. In examples where camera 504 is rear facing towards a user, camera 504 may capture images or videos associated with surface 506. In examples where camera 504 is front facing away from a user, camera 504 may capture images or videos of an area. HMD 500 may be designed to have both front facing and rear facing cameras (e.g., camera 504). There may be multiple cameras 504 that may be used to detect the reflection off of surface 506 or other movements (e.g., glint or any other suitable characteristic). Camera 504 may be located on frame 502 in different positions. Camera 504 may be located along a width of a section of frame 502. In some other examples, the camera 504 may be arranged on one side of frame 502 (e.g., a side of frame 502 nearest to the eye). Alternatively, in some examples, the camera 504 may be located on display 508. In some examples, camera 504 may be sensors or a combination of cameras and sensors to track eye (e.g., surface 506) of a user.

Audio device 510 may be located on frame 502 in different positions or any other configuration such as but not limiting to headphone(s) communicatively connected to HMD 500, a peripheral device, or the like. Audio device 510 may be located along a width of a section of frame 502. In some other examples, the audio device may be arranged on sides of frame 502 (e.g., a side of frame 502 nearest to the car). In some examples, audio device 510 may be sensors or a combination of speakers, microphones, and sensors to capture and produce sound associated with a user.

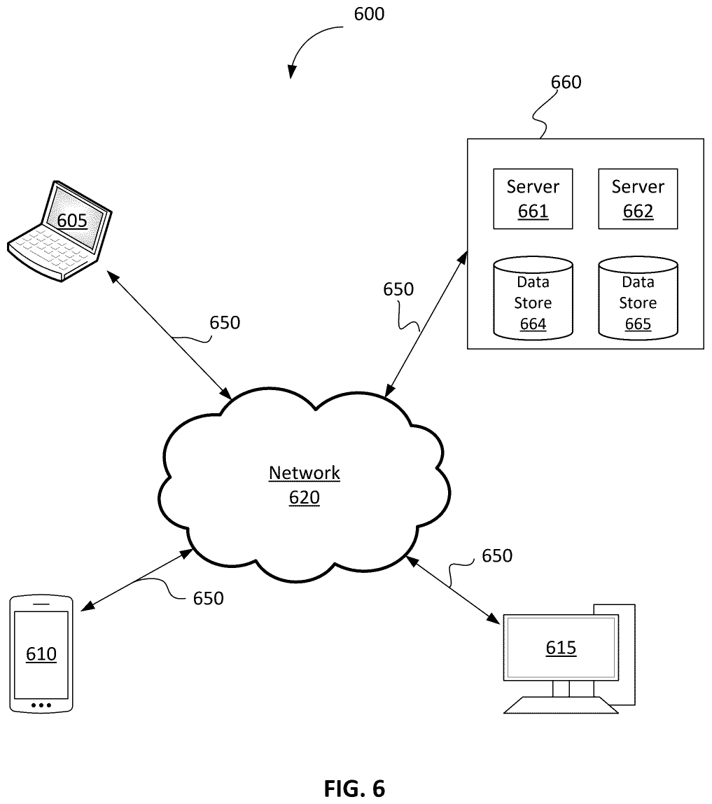

Reference is now made to FIG. 6, which is a block diagram of a system according to exemplary embodiments. As shown in FIG. 6, the system 600 may include one or more communication devices 605, 610, and 615 and a network device 660. Additionally, the system 600 may include any suitable network such as, for example, network 620. As an example and not by way of limitation, one or more portions of network 620 may include an ad hoc network, an intranet, an extranet, a virtual private network (VPN), a local area network (LAN), a wireless LAN (WLAN), a wide area network (WAN), a wireless WAN (WWAN), a metropolitan area network (MAN), a portion of the Internet, a portion of the Public Switched Telephone Network (PSTN), a cellular telephone network, or a combination of two or more of these. Network 620 may include one or more networks 620.

Links 650 may connect the communication devices 605, 610, and 615 to network 620, network device 660 and/or to each other. This disclosure contemplates any suitable links 650. In some exemplary embodiments, one or more links 650 may include one or more wireline (such as for example Digital Subscriber Line (DSL) or Data Over Cable Service Interface Specification (DOCSIS)), wireless (such as for example Wi-Fi or Worldwide Interoperability for Microwave Access (WiMAX)), or optical (such as for example Synchronous Optical Network (SONET) or Synchronous Digital Hierarchy (SDH)) links. In some exemplary embodiments, one or more links 650 may each include an ad hoc network, an intranet, an extranet, a VPN, a LAN, a WLAN, a WAN, a WWAN, a MAN, a portion of the Internet, a portion of the PSTN, a cellular technology-based network, a satellite communications technology-based network, another link 650, or a combination of two or more such links 650. Links 650 need not necessarily be the same throughout system 600. One or more first links 650 may differ in one or more respects from one or more second links 650.

In some exemplary embodiments, communication devices 605, 610, 615 may be electronic devices including hardware, software, or embedded logic components or a combination of two or more such components and capable of carrying out the appropriate functionalities implemented or supported by the communication devices 605, 610, 615. As an example, and not by way of limitation, the communication devices 605, 610, 615 may be a computer system such as for example a desktop computer, notebook or laptop computer, netbook, a tablet computer (e.g., a smart tablet), e-book reader, Global Positioning System (GPS) device, camera, personal digital assistant (PDA), handheld electronic device, cellular telephone, smartphone, smart glasses, augmented/virtual reality device, smart watches, charging case, or any other suitable electronic device, or any suitable combination thereof. The communication devices 605, 610, 615, may enable one or more users to access network 620. The communication devices 605, 610, 615 may enable a user(s) to communicate with other users at other communication devices 605, 610, 615.

Network device 660 may be accessed by the other components of system 600 either directly or via network 620. As an example, and not by way of limitation, communication devices 605, 610, 615 may access network device 660 using a web browser or a native application associated with network device 660 (e.g., a mobile social-networking application, a messaging application, another suitable application, or any combination thereof) either directly or via network 620. In particular exemplary embodiments, network device 660 may include one or more servers 662. Each server 662 may be a unitary server or a distributed server spanning multiple computers or multiple datacenters. Servers 662 may be of various types, such as, for example and without limitation, web server, news server, mail server, message server, advertising server, file server, application server, exchange server, database server, proxy server, another server suitable for performing functions or processes described herein, or any combination thereof. In particular exemplary embodiments, each server 662 may include hardware, software, or embedded logic components or a combination of two or more such components for carrying out the appropriate functionalities implemented and/or supported by server 662. In particular exemplary embodiments, network device 660 may include one or more data stores 664, 665. Data stores 664, 665 may be used to store various types of information. In particular exemplary embodiments, the information stored in data stores 664, 665 may be organized according to specific data structures. In particular exemplary embodiments, each data store 664, 665 may be a relational, columnar, correlation, or other suitable database. Although this disclosure describes or illustrates particular types of databases, this disclosure contemplates any suitable types of databases. Particular exemplary embodiments may provide interfaces that enable communication devices 605, 610, 615 and/or another system (e.g., a third-party system) to manage, retrieve, modify, add, or delete, the information stored in data store 664, 665.

Network device 660 may provide users of the system 600 the ability to communicate and interact with other users. In particular exemplary embodiments, network device 660 may provide users with the ability to take actions on various types of items or objects, supported by network device 660. In particular exemplary embodiments, network device 660 may be capable of linking a variety of entities. As an example, and not by way of limitation, network device 660 may enable users to interact with each other as well as receive content from other systems (e.g., third-party systems) or other entities, or to allow users to interact with these entities through an application programming interfaces (API) or other communication channels.

It should be pointed out that although FIG. 6 shows one network device 660 and four communication devices 605, 610, and 615 any suitable number of network devices 660 and communication devices 605, 610, and 615 may be part of the system of FIG. 6 without departing from the spirit and scope of the present disclosure.

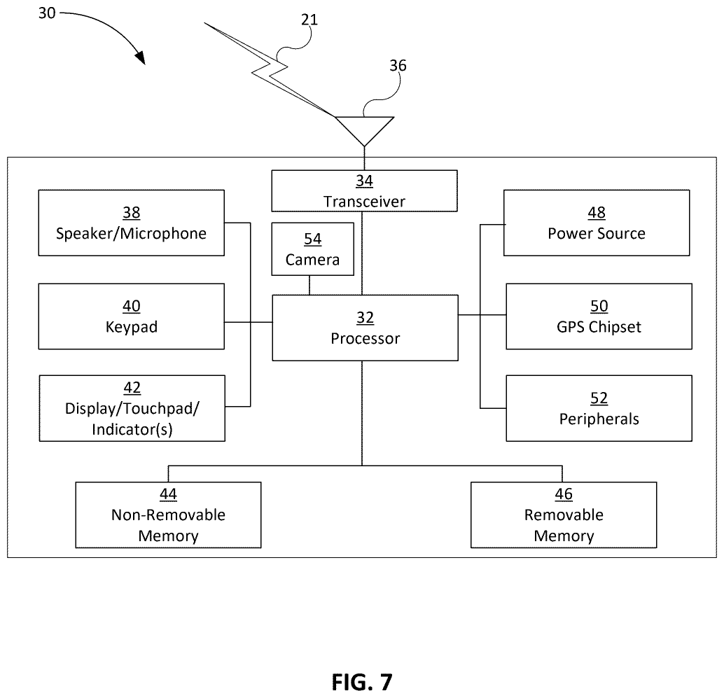

FIG. 7 illustrates a block diagram of an exemplary hardware/software architecture of a communication device such as, for example, user equipment (UE) 30. In some exemplary embodiments, the UE 30 may be any of communication devices 605, 610, 615. In some exemplary embodiments, the UE 30 may be a computer system such as for example a desktop computer, notebook or laptop computer, netbook, a tablet computer (e.g., a smart tablet), e-book reader, GPS device, camera, personal digital assistant, handheld electronic device, cellular telephone, smartphone, smart glasses, augmented/virtual reality device, smart watch, charging case, or any other suitable electronic device. As shown in FIG. 7, the UE 30 (also referred to herein as node 30) may include a processor 32, non-removable memory 44, removable memory 46, a speaker/microphone 38, a keypad 40, a display, touchpad, and/or indicators 42, a power source 48, a global positioning system (GPS) chipset 50, and other peripherals 52. The power source 48 may be capable of receiving electric power for supplying electric power to the UE 30. For example, the power source 48 may include an alternating current to direct current (AC-to-DC) converter allowing the power source 48 to be connected/plugged to an AC electrical receptable and/or Universal Serial Bus (USB) port for receiving electric power. The UE 30 may also include a camera 54. In an exemplary embodiment, the camera 54 may be a smart camera configured to sense images/video appearing within one or more bounding boxes. The UE 30 may also include communication circuitry, such as a transceiver 34 and a transmit/receive element 36. It will be appreciated the UE 30 may include any sub-combination of the foregoing elements while remaining consistent with an embodiment. In an example embodiment in which the UE 30 may be a charging case (also referred to herein as carrying case, companion case), the charging case may be a charging case for smart glasses, smart watches, and/or other smart devices. The charging case may include one or more microphones (e.g., microphone 38) and wireless functionality built in, to be communicatively coupled and/or paired to smart glasses, smart watches, and/or other smart devices. The charging case may communicate content (e.g., audio, video, images, etc.) to the smart glasses, smart watches and/or other smart devices via one or more signals such as, for example, electromagnetic signals (e.g., a radio frequency signal(s), a Wi-Fi signal(s), a Bluetooth signal(s)) in instances in which the smart watches, smart glasses and/or other smart devices are within the charging case and/or within a proximity (e.g., located a few feet or yards) to the charging case. In some example embodiments, the charging case may have a camera (e.g., camera 54).

The processor 32 may be a special purpose processor, a digital signal processor (DSP), a plurality of microprocessors, one or more microprocessors in association with a DSP core, a controller, a microcontroller, Application Specific Integrated Circuits (ASICs), Field Programmable Gate Array (FPGAs) circuits, any other type of integrated circuit (IC), a state machine, and the like. In general, the processor 32 may execute computer-executable instructions stored in the memory (e.g., memory 44 and/or memory 46) of the node 30 in order to perform the various required functions of the node. For example, the processor 32 may perform signal coding, data processing, power control, input/output processing, and/or any other functionality that enables the node 30 to operate in a wireless or wired environment. The processor 32 may run application-layer programs (e.g., browsers) and/or radio access-layer (RAN) programs and/or other communications programs. The processor 32 may also perform security operations such as authentication, security key agreement, and/or cryptographic operations, such as at the access-layer and/or application layer for example.

The processor 32 is coupled to its communication circuitry (e.g., transceiver 34 and transmit/receive element 36). The processor 32, through the execution of computer executable instructions, may control the communication circuitry in order to cause the node 30 to communicate with other nodes via the network to which it is connected.

The transmit/receive element 36 may be configured to transmit signals to, or receive signals from, other nodes or networking equipment. For example, in an exemplary embodiment, the transmit/receive element 36 may be an antenna configured to transmit and/or receive radio frequency (RF) signals. The transmit/receive element 36 may support various networks and air interfaces, such as wireless local area network (WLAN), wireless personal area network (WPAN), cellular, and the like. In yet another exemplary embodiment, the transmit/receive clement 36 may be configured to transmit and/or receive both RF and light signals. It will be appreciated that the transmit/receive element 36 may be configured to transmit and/or receive any combination of wireless or wired signals.

The transceiver 34 may be configured to modulate the signals that are to be transmitted by the transmit/receive element 36 and to demodulate the signals that are received by the transmit/receive clement 36. As noted above, the node 30 may have multi-mode capabilities. Thus, the transceiver 34 may include multiple transceivers for enabling the node 30 to communicate via multiple radio access technologies (RATs), such as universal terrestrial radio access (UTRA) and Institute of Electrical and Electronics Engineers (IEEE 802.11), for example.

The processor 32 may access information from, and store data in, any type of suitable memory, such as the non-removable memory 44 and/or the removable memory 46. For example, the processor 32 may store session context in its memory, as described above. The non-removable memory 44 may include RAM, ROM, a hard disk, or any other type of memory storage device. The removable memory 46 may include a subscriber identity module (SIM) card, a memory stick, a secure digital (SD) memory card, and the like. In other exemplary embodiments, the processor 32 may access information from, and store data in, memory that is not physically located on the node 30, such as on a server or a home computer.

The processor 32 may receive power from the power source 48 and may be configured to distribute and/or control the power to the other components in the node 30. The power source 48 may be any suitable device for powering the node 30. For example, the power source 48 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like. The processor 32 may also be coupled to the GPS chipset 50, which may be configured to provide location information (e.g., longitude and latitude) regarding the current location of the node 30. It will be appreciated that the node 30 may acquire location information by way of any suitable location-determination method while remaining consistent with an exemplary embodiment.

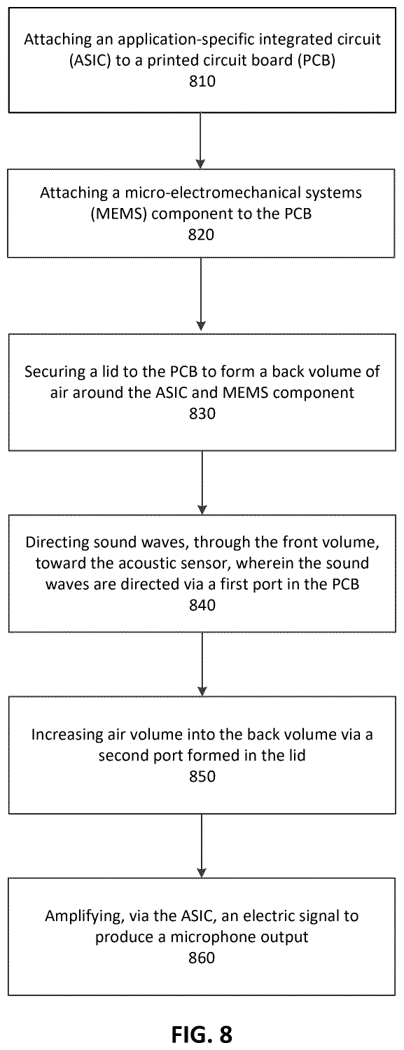

FIG. 8 illustrates a flowchart to form a microphone system (e.g., MEMS microphone package 100). At block 810, exemplary aspects may attach an application-specific integrated circuit (ASIC) (e.g., ASIC 115) to a printed circuit board (PCB) (e.g., PCB 120).

At block 820, exemplary aspects may attach a micro-electromechanical systems (MEMS) component (e.g., MEMS component 105) to the PCB (e.g., PCB 120). In some examples, the MEMS component may include at least one of: a plate (e.g., plate 107), an acoustic sensor (e.g., acoustic sensor 106), or a MEMS die substrate (e.g., MEMS die substrate 108). A front volume (e.g., front volume V1) of air may be formed between the PCB and the acoustic sensor. In an example a port (e.g., port 125) is formed in the PCB (e.g., PCB 120). In an example, the acoustic sensor (e.g., acoustic sensor 106) includes an acoustic membrane (see e.g., acoustic sensor 106) that vibrates in response to the directed sound waves. In some examples, the acoustic membrane may be positioned within the front volume, such as in front of the acoustic sensor. The acoustic membrane may block particles from entering the acoustic sensor.

At block 830, exemplary aspects may secure a lid (e.g., lid 110) to the PCB to form a back volume (e.g., V2) of air around the ASIC and MEMS component. In examples, aspects may increase air volume into the back volume (e.g., V2) to increase at least one of a sensitivity or a signal-to-noise ratio (SNR) of the MEMS component.

At block 840, exemplary aspects may direct sound waves, through the front volume (e.g., V1), toward the acoustic sensor, wherein the sound waves are directed via a first port (e.g., port 125, port 225, port 330) in the PCB (e.g., PCB 120).

At block 850, exemplary aspects may increase air volume into the back volume via a second port (e.g., port 230, port 325) formed in the lid (e.g., lid 110). In various examples, a first membrane (e.g., membrane 235) may cover the first port and a second membrane (e.g., mesh 256) may cover the second port. At least one of the first membrane or the second membrane is an expanded polytetrafluoroethylene material. At least one of the first membrane of the second membrane blocks at least one of: debris, foreign material, water ingress, or particulate matter from passing through to the respective port.

In some examples, exemplary aspects may form a third air volume (e.g., V3) by an enclosure (e.g., enclosure 340) surrounding the lid and the PCB. An opening (e.g., opening 260) in the enclosure may direct sound waves toward the first port. In additional examples, a mesh (e.g., mesh 256) may be positioned between an opening of an enclosure and the second port, wherein the mesh blocks at least one of: debris, foreign material, water ingress, or particulate matter from passing through the second port into the front volume.

At block 860, exemplary aspects may amplify, convert, or otherwise transform, via the ASIC, an electric signal to produce a microphone output. According to various examples, the microphone system may be incorporated into a device (e.g., HMD 500). The device may be at least one of: a desktop computer, a notebook computer, a laptop computer, a netbook, a tablet computer, an e-book reader, a Global Positioning System (GPS) device, a camera, a personal digital assistant (PDA), a handheld electronic device, a cellular telephone, a smartphone, a head-mounted device, an augmented reality device, a virtual reality device, a smart watch, or a charging case. In an example, the device may be the head-mounted device, and the microphone system may be secured to a frame of the head-mounted device.

The foregoing description of the embodiments has been presented for the purpose of illustration; it is not intended to be exhaustive or to limit the patent rights to the precise forms disclosed. Persons skilled in the relevant art can appreciate that many modifications and variations are possible in light of the above disclosure.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments also may relate to an apparatus for performing the operations herein. This apparatus may be specially constructed for the required purposes, and/or it may comprise a computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments also may relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the inventive subject matter. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed:

1. A microphone system comprising:
a printed circuit board (PCB);
an application-specific integrated circuit (ASIC) attached to the PCB, wherein the ASIC produces a microphone output from an electrical signal;
a micro-electromechanical systems (MEMS) component attached to the PCB, wherein the MEMS component comprises a plate, an acoustic sensor, and a MEMS die substrate, and wherein a front volume of air is formed between the PCB and the acoustic sensor;
a lid secured to the PCB, wherein the lid forms a back volume of air around the ASIC and the MEMS component;
a first port formed in the PCB, wherein the first port is positioned to direct sound waves, through the front volume, toward the acoustic sensor; and
a second port formed in the lid to increase air volume into the back volume.

2. The microphone system of claim 1, wherein the acoustic sensor comprises an acoustic membrane that vibrates in response to the directed sound waves.

3. The microphone system of claim 1, further comprising a membrane covering the second port, wherein the membrane blocks at least one of: debris, foreign material, water ingress, or particulate matter from passing through the second port.

4. The microphone system of claim 1, further comprising an enclosure forming a third air volume surrounding the lid and the PCB.

5. The microphone system of claim 4, wherein the enclosure comprises an opening to direct sound waves toward the first port.

6. The microphone system of claim 5, further comprising a mesh positioned between the opening of the enclosure and the second port, wherein the mesh blocks at least one of: debris, foreign material, water ingress, or particulate matter from passing through the second port into the front volume.

7. The microphone system of claim 1, wherein a material covers at least one of the first port and the second port.

8. The microphone system of claim 7, wherein the material is an expanded polytetrafluoroethylene membrane.

9. The microphone system of claim 1, wherein air volume through the second port and into the back volume increases at least one of a sensitivity or a signal-to-noise ratio (SNR) of the MEMS component.

10. The microphone system of claim 1, wherein the microphone system is incorporated into a device, wherein the device is at least one of: a desktop computer, a notebook computer, a laptop computer, a netbook, a tablet computer, an e-book reader, a Global Positioning System (GPS) device, a camera, a personal digital assistant (PDA), a handheld electronic device, a cellular telephone, a smartphone, a head-mounted device, an augmented reality device, a virtual reality device, a smart watch, or a charging case.

11. A method to form a microphone system, comprising:
attaching an application-specific integrated circuit (ASIC) to a printed circuit board (PCB);
attaching a micro-electromechanical systems (MEMS) component to the PCB, wherein the MEMS component comprises a plate, an acoustic sensor, and a MEMS die substrate, and wherein a front volume of air is formed between the PCB and the acoustic sensor;
securing a lid to the PCB to form a back volume of air around the ASIC and the MEMS component;
directing sound waves, through the front volume, toward the acoustic sensor, wherein the sound waves are directed via a first port in the PCB;
increasing air volume into the back volume via a second port formed in the lid; and
producing, via the ASIC, a microphone output via an electric signal.

12. The method of claim 11, further comprising:
vibrating an acoustic membrane positioned within the front volume, in front of the acoustic sensor, in response to the directed sound waves.

13. The method of claim 11, further comprising:
covering the first port with a first membrane and covering the second port with a second membrane.

14. The method of claim 13, wherein at least one of the first membrane or the second membrane is an expanded polytetrafluoroethylene material.

15. The method of claim 11, further comprising:
forming a third air volume by an enclosure surrounding the lid and the PCB.

16. The method of claim 15, further comprising:
directing sound waves toward the first port, wherein the sound waves are directed toward the first port through an opening in the enclosure.

17. The method of claim 15, further comprising:
positioning a mesh between an opening of the enclosure and the second port, wherein the mesh blocks at least one of: debris, foreign material, water ingress, or particulate matter from passing through the second port into the front volume.

18. The method of claim 11, further comprising:
increasing air volume into the back volume to increase at least one of a sensitivity or a signal-to-noise ratio (SNR) of the MEMS component.

19. The method of claim 11, further comprising:
incorporating the microphone system into a device, wherein the device is at least one of:
a desktop computer, a notebook computer, a laptop computer, a netbook, a tablet computer, an e-book reader, a Global Positioning System (GPS) device, a camera, a personal digital assistant (PDA), a handheld electronic device, a cellular telephone, a smartphone, a head-mounted device, an augmented reality device, a virtual reality device, a smart watch, or a charging case.

20. A microphone system comprising:
a printed circuit board (PCB);
an application-specific integrated circuit (ASIC) attached to the PCB, wherein the ASIC produces a microphone output from an electrical signal;
a micro-electromechanical systems (MEMS) component attached to the PCB, wherein the MEMS component comprises a plate, an acoustic sensor, and a MEMS die substrate, and wherein a front volume of air is formed between the PCB and the acoustic sensor;
a lid secured to the PCB, wherein the lid forms a back volume of air around the ASIC and the MEMS component;
a first port formed in the PCB, wherein the first port is positioned to direct sound waves, through the front volume, toward the acoustic sensor;
a second port formed in the lid to increase air volume into the back volume;
an enclosure surrounding the lid and the PCB, wherein the enclosure comprises an opening to direct the sound waves to the first port; and
a flex securing the enclosure to the PCB.
